(19) United States
(12) Patent Application Publication
(10) Pub. No.: US 2024/0244892 A1
(43) Pub. Date: Jul. 18, 2024

(54) DISPLAY DEVICE

(71) Applicant: Samsung Display Co., LTD., Yongin-si (KR)

(72) Inventors: Song Ee LEE, Yongin-si (KR); Sang Ji PARK, Yongin-si (KR); Cheol SHIN, Yongin-si (KR); Keun Chan OH, Yongin-si (KR); DOKYUNG YOUN, Yongin-si (KR); Sun-Kyu JOO, Yongin-si (KR); Woo-Man JI, Yongin-si (KR); You Young JIN, Yongin-si (KR); Tae Hyung HWANG, Yongin-si (KR)

(73) Assignee: Samsung Display Co., LTD., Yongin-si (KR)

(21) Appl. No.: 18/512,316

(22) Filed: Nov. 17, 2023

(30) Foreign Application Priority Data
Jan. 18, 2023 (KR) 10-2023-0007349

(51) Int. Cl. H10K 59/122; H10K 59/38; H10K 59/80

(52) U.S. Cl. CPC H10K 59/122; H10K 59/38; H10K 59/873

(57) ABSTRACT

A display device includes multiple light emitting devices disposed on a substrate, each including a first electrode, an emission layer, and a second electrode, a pixel defining layer including multiple openings overlapping the first electrode in a plan view, an encapsulation layer covering the light emitting devices and including multiple first openings overlapping the pixel defining layer in a plan view, a bank disposed on the encapsulation layer, overlapping the first openings in a plan view, and including multiple second openings overlapping the light emitting devices in a plan view, a first color conversion layer, a second color conversion layer, and a transmission layer, each disposed inside the second openings, and a spacer disposed on the bank and including a colored material.

### CROSS REFERENCE TO RELATED APPLICATION(S)

This application claims priority to and benefits of Korean Patent Application No. 10-2023-0007349 under 35 U.S.C. § 119, filed on Jan. 18, 2023, in the Korean Intellectual Property Office (KIPO), the entire contents of which are incorporated herein by reference.

### BACKGROUND

### 1. Technical Field

The disclosure relates to a display device with improved color mixing.

### 2. Description of the Related Art

A display device is a device that displays an image, and includes a liquid crystal display (LCD), an organic light emitting diode (OLED) display, a quantum dot light emitting diode (QLED), a micro LED display, or the like.

Such a display device is used in various electronic devices such as a smartphone, a mobile phone, a tablet PC, a monitor, a television, a multimedia player, a video game console, and the like.

Recently, a display device including a color conversion panel has been developed to implement a display device with high efficiency. The color conversion panel may convert incident light into light of a different wavelength or transmit it.

The above information disclosed in this Background section is only for enhancement of understanding of the background of the described technology, and therefore, it may contain information that does not form a prior art that is already known in this country to a person of ordinary skill in the art.

### SUMMARY

Although a plurality of light emitting devices are spaced apart from each other by a certain distance, color mixing between adjacent ones of the light emitting devices may occur. The disclosure provides a display device with improved color mixing.

According to an embodiment of the disclosure, a display device may include a plurality of light emitting devices disposed on a substrate, each including a first electrode, an emission layer, and a second electrode, a pixel defining layer including a plurality of openings overlapping the first electrode in a plan view, an encapsulation layer covering the plurality of light emitting devices and including a plurality of first openings overlapping the pixel defining layer in a plan view, a bank disposed on the encapsulation layer, overlapping the plurality of first openings in a plan view, and having a plurality of second openings overlapping the plurality of light emitting devices in a plan view, a first color conversion layer, a second color conversion layer, and a transmission layer, each disposed inside the plurality of second openings, and a spacer disposed on the bank and including a colored material.

The plurality of second openings may each include a first emission area overlapping the transmission layer in a plan view, a second emission area overlapping the first color conversion layer in a plan view, and a third emission area overlapping the second color conversion layer in a plan view.

The display device may further include a first color filter overlapping the transmission layer in a plan view, a second color filter overlapping the first color conversion layer in a plan view, and a third color filter overlapping the second color conversion layer in a plan view.

The display device may further include a first dummy color filter disposed on the spacer, a second dummy color filter disposed on the first dummy color filter, and a third dummy color filter disposed on the second dummy color filter.

The spacer may surround a portion of at least one of the first emission area, the second emission area, and the third emission area in a plan view.

The spacer may completely surround at least one of the first emission area, the second emission area, and the third emission area in a plan view.

The encapsulation layer may include an organic encapsulation layer including the plurality of first openings overlapping the pixel defining layer in a plan view, and an inorganic encapsulation layer disposed on the organic encapsulation layer.

The bank may contact the inorganic encapsulation layer.

At least a portion of the bank may be disposed inside the plurality of first openings.

The pixel defining layer, the bank, the spacer, the first dummy color filter, the second dummy color filter, and the third dummy color filter may overlap each other in a plan view.

According to an embodiment of the disclosure, a display device may include a display panel, and a color filter panel overlapping the display panel in a plan view. The display panel may include a first substrate, a plurality of light emitting devices disposed on the first substrate, each including a first electrode, an emission layer, and a second electrode, a pixel defining layer including a plurality of openings overlapping the plurality of first electrodes in a plan view, an encapsulation layer covering the plurality of light emitting devices and including a plurality of first openings overlapping the pixel defining layer in a plan view, a bank disposed on the encapsulation layer, overlapping the plurality of first openings in a plan view, and including a plurality of second openings overlapping the plurality of light emitting devices in a plan view, and a first color conversion layer, a second color conversion layer, and a transmission layer, each disposed inside the plurality of second openings. The color filter panel may include a second substrate, a color filter disposed on the second substrate, and a spacer disposed on the color filter and including a colored material.

The plurality of second openings may each include a first emission area overlapping the transmission layer in a plan view, a second emission area overlapping the first color conversion layer in a plan view, and a third emission area overlapping the second color conversion layer in a plan view.

The color filter may include a first color filter overlapping the transmission layer in a plan view, a second color filter overlapping the first color conversion layer in a plan view, and a third color filter overlapping the second color conversion layer in a plan view.

The color filter may further include a first dummy color filter overlapping the spacer in a plan view, a second dummy color filter overlapping the first dummy color filter in a plan view, and a third dummy color filter overlapping the second dummy color filter in a plan view.

The spacer may surround a portion of at least one of the first emission area, the second emission area, and the third emission area in a plan view.

The spacer may completely surround at least one of the first emission area, the second emission area, and the third emission area in a plan view.

The encapsulation layer may include an organic encapsulation layer including the plurality of first openings overlapping the pixel defining layer in a plan view, and an inorganic encapsulation layer disposed on the organic encapsulation layer.

The bank may contact the inorganic encapsulation layer.

At least a portion of the bank may be disposed inside the plurality of first openings.

The pixel defining layer, the bank, the spacer, the first dummy color filter, the second dummy color filter, and the third dummy color filter may overlap each other in a plan view.

According to embodiments, it is possible to provide a display device with improved color mixing.

### BRIEF DESCRIPTION OF THE DRAWINGS

FIG. 1 is a schematic plan view of an emission area of a display device according to an embodiment.

FIG. 2 is a schematic cross-sectional view taken along line A-A′ of FIG. 1.

FIG. 3 is a schematic cross-sectional view of a stacked structure on a first substrate of a display device according to an embodiment.

FIG. 4 is a schematic cross-sectional view of a stacked structure on a first substrate of a display device according to an embodiment.

FIG. 5 is a schematic cross-sectional view of a stacked structure on a second substrate of a display device according to an embodiment.

FIG. 6 is a schematic cross-sectional view of a stacked structure on a second substrate of a display device according to an embodiment.

FIG. 7 is a schematic plan view of emission areas of a display device according to an embodiment.

FIG. 8 is a schematic plan view of emission areas of a display device according to an embodiment.

FIG. 9 is a schematic plan view of emission areas of a display device according to an embodiment.

FIG. 10 is a schematic plan view of emission areas of a display device according to an embodiment.

FIG. 11 is a schematic plan view of emission areas of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

To clearly describe the disclosure, parts that are irrelevant to the description are omitted, and like numerals refer to like or similar constituent elements throughout the specification.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, when an embodiment may be implemented differently, a specific process order may be performed differently from the described order. For example, two consecutively described processes may be performed substantially at the same time or performed in an order opposite to the described order.

Further, since sizes and thicknesses of constituent members shown in the accompanying drawings are arbitrarily given for better understanding and ease of description, the disclosure is not limited to the illustrated sizes and thicknesses. In the drawings, the thicknesses of layers, films, panels, regions, etc., are exaggerated for clarity. In the drawings, for better understanding, and ease of description, the thicknesses of some layers and areas are exaggerated.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. To this end, the term “connected” may refer to physical, electrical, and/or fluid connection, with or without intervening elements.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Unless explicitly described to the contrary, the word “comprise,” “include,” and variations such as “comprises,” “comprising,” “includes,” and/or “including” will be understood to imply the inclusion of stated elements but not the exclusion of any other elements.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, in the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Spatially relative terms, such as “under,” “lower,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

Further, throughout the specification, the phrase “in a plan view” means when an object portion is viewed from above, and the phrase “in a cross-sectional view” means when a cross- section taken by vertically cutting an object portion is viewed from the side.

To overlap two constituent elements means that two constituent elements are overlapped in a plan view (e.g., a direction perpendicular to an upper surface of the substrate, a thickness direction of the substate) unless stated otherwise.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

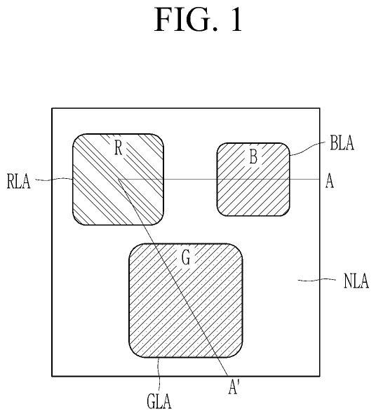

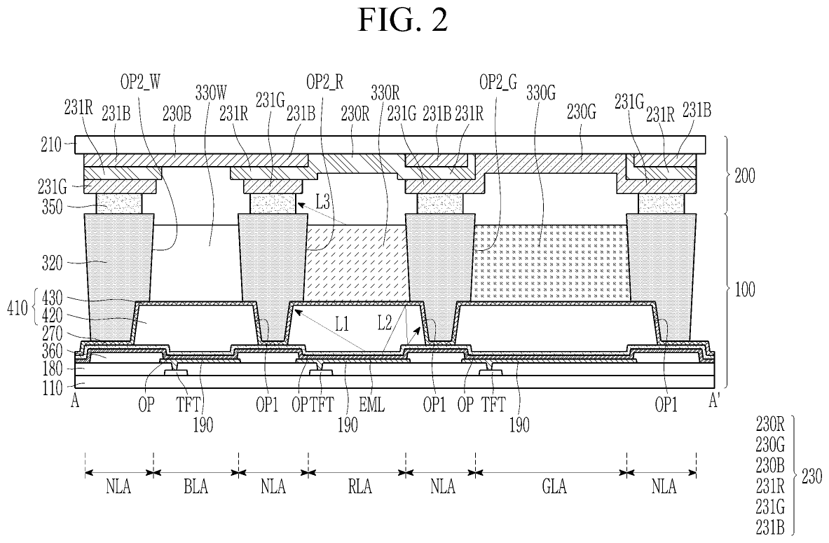

FIG. 1 is a schematic plan view of an emission area of a display device according to an embodiment. FIG. 2 is a schematic cross-sectional view taken along line A-A′ of FIG. 1. Embodiments will be described with reference to FIG. 1 and FIG. 2.

In FIG. 1, three adjacent emission areas BLA, RLA, and GLA and a non-emission area NLA disposed around the emission areas BLA, RLA, and GLA are schematically illustrated. For example, the emission areas BLA, RLA, and GLA may include a blue emission area (or a first emission area) BLA, a red emission area (or a second emission area) RLA, and a green emission area (or a third emission area) GLA. Each emission area BLA, RLA, or GLA may correspond to a pixel. For example, the blue emission area BLA, the red emission area RLA, and the green emission area GLA may correspond to a blue pixel, a red pixel, and a green pixel, respectively. Each emission area BLA, RLA, or GLA is illustrated as a rectangular shape with rounded corners in a plan view, but the disclosure is not limited thereto, and each emission area BLA, RLA, or GAL may have different shapes such as rhombus, pentagon, octagon, the like, or a combination thereof, and may have various shapes, areas, and the like according to an embodiment.

Referring to FIG. 2, each of the emission areas BLA, RLA, and GLA may include an emission layer EML. The emission layer EML may include a light emitting material emitting blue light. The emission layer EML may include a light emitting material that emits red light or green light (in addition to blue light).

Each of the emission areas BLA, RLA, and GLA may include color conversion layers 330R and 330G or a transmission layer 330W. The color conversion layers 330R and 330G and the transmission layer 330W may be partitioned by multiple banks 320.

A pixel defining layer 360, a bank 320, a spacer 350, and the like may be disposed in the non-emission area NLA and partition each emission area BLA, RLA, or GLA. The pixel defining layer 360, the bank 320, and/or the spacer 350 may include a light-blocking material and block light and prevent color mixing between adjacent emission areas BLA, RLA, and GLA. The pixel defining layer 360, the bank 320, and/or the spacer 350 may overlap (e.g., at least partially overlap) each other in a plan view.

A display device according to an embodiment may include a display panel 100 including a color conversion layer 330R or 330G and a color filter panel 200. In another embodiment, the color conversion layer 330R or 330G may be included in the color filter panel 200.

In an embodiment, the display panel 100 may include a first substrate 110 (or a substate), multiple light emitting devices, a pixel defining layer 360, an encapsulation layer 410, a bank 320, a first color conversion layer 330R, a second color conversion layer 330G, and a transmission layer 330W, and the color filter panel 200 may include a second substrate 210, a color filter 230, and a spacer 350. The display panel 100 may include a first substrate 110 (or a substrate), multiple transistors TFT disposed on the first substrate 110, and an insulating layer 180 disposed on the first substrate 110 and the transistors TFT. A first electrode 190 and a pixel defining layer 360 may be disposed on the insulating layer 180. The first electrode 190 may be electrically connected to the transistors TFT. The pixel defining layer 360 may have an opening OP overlapping the first electrode 190 in a plan view, and may cover an edge of the first electrode 190.

The emission layer EML may be disposed on the first electrode 190, and the second electrode 270 may be disposed on the emission layer EML. The emission layer EML may overlap the first electrode 190 and the second electrode 270 in a plan view. The first electrode 190, the emission layer EML, and the second electrode 270 may constitute a light emitting device such as a light emitting diode LED and the like.

An encapsulation layer 410 may be disposed on the light emitting device. The encapsulation layer 410 may encapsulate the light emitting device and protect the light emitting device from an external environment. The encapsulation layer 410 may include at least one inorganic encapsulation layer and at least one organic encapsulation layer. For example, the encapsulation layer 410 may have a three-layer structure in which an inorganic encapsulation layer, an organic encapsulation layer, and an inorganic encapsulation layer are sequentially stacked.

In an embodiment, the encapsulation layer 410 may include an organic encapsulation layer (for example, a patterned organic encapsulation layer) 420 and an inorganic encapsulation layer 430 disposed on the organic encapsulation layer 420. In another embodiment, an inorganic encapsulation layer (not illustrated) may be further included between the light emitting device and the organic encapsulation layer 420.

The organic encapsulation layer 420 may be patterned and include a first opening OP1 in an area overlapping (e.g., partially overlapping) the pixel defining layer 360 in a plan view. The inorganic encapsulation layer 430 may be disposed on an entire surface of the first substrate 110, and may include a concave portion corresponding to the first opening OP1 of the organic encapsulation layer 420. The encapsulation layer 410 may include multiple first openings OP1 patterned and overlapping (e.g., partially overlapping) the pixel defining layer 360 in a plan view.

The bank 320 may be disposed on the encapsulation layer 410. For example, a lower surface of the bank 320 may contact an upper surface of the inorganic encapsulation layer 430. The bank 320 may include second openings OP2_W, OP2_R, and OP2_G corresponding to light emitting devices. The bank 320 may overlap the pixel defining layer 360 in a plan view (or in a direction perpendicular to a surface of the first substrate 110, or in a thickness direction of the first substrate 110). The bank 320 may overlap (e.g., partially overlap) the first opening OP1 of the patterned organic encapsulation layer 420 in a plan view. A portion of the bank 320 may be disposed inside first opening OP1. The bank 320 may partition the color conversion layers 330R and 330G and the transmission layer 330W. The color conversion layers 330R and 330G and the transmission layer 330W may be disposed inside the second openings OP2_W, OP2_R, and OP2_G of the bank 320.

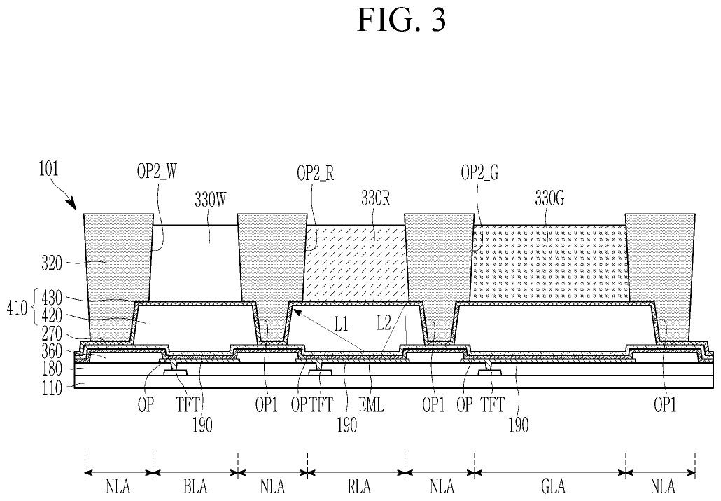

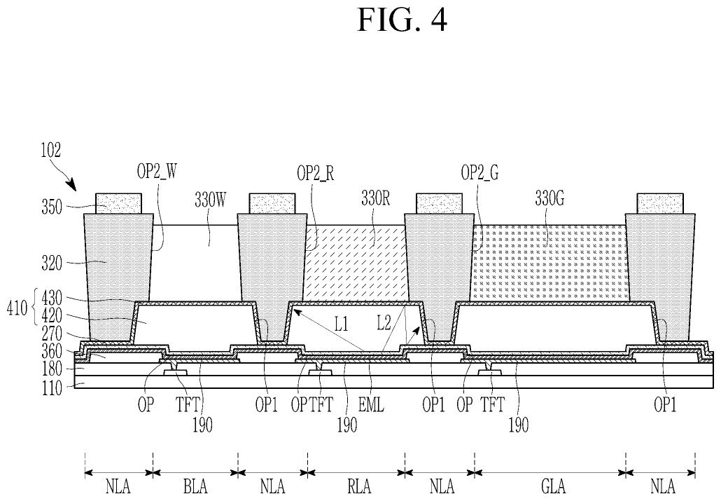

The bank 320 may prevent color mixing between adjacent emission areas BLA, RLA, and GLA by including a light blocking material. In another embodiment, as a portion of the bank 320 is disposed inside the first opening OP1, lights L1 and L2 incident from the light emitting device may be absorbed by the bank 320 without transmitting to an adjacent emission area BLA, RLA, or GLA, thereby preventing color mixing between adjacent pixels. A specific stacked structure disposed on the first substrate 110 of the display panel 100 will be described in detail with reference to FIG. 3 and FIG. 4.

A spacer 350 may be disposed on the bank 320. The spacer 350 may overlap the pixel definition layer 360 and the bank 320 in a plan view. The spacer 350 may be disposed adjacent to the emission area BLA, RLA, or GLA. The spacer 350 may surround at least a portion of the emission areas BLA, RLA, and GLA in a plan view. In an embodiment, the spacer 350 may include a colored material and block light, and may prevent (or block) color mixing between adjacent ones (or neighboring ones) of the emission areas BLA, RLA, and GLA. For example, light (e.g., blue light) L3 not converted in (or excited by) the color conversion layer 330R or 330G may be absorbed by the spacer 350 and not propagate to an adjacent emission area BLA, RLA, or GLA, thereby preventing (or blocking) color mixing.

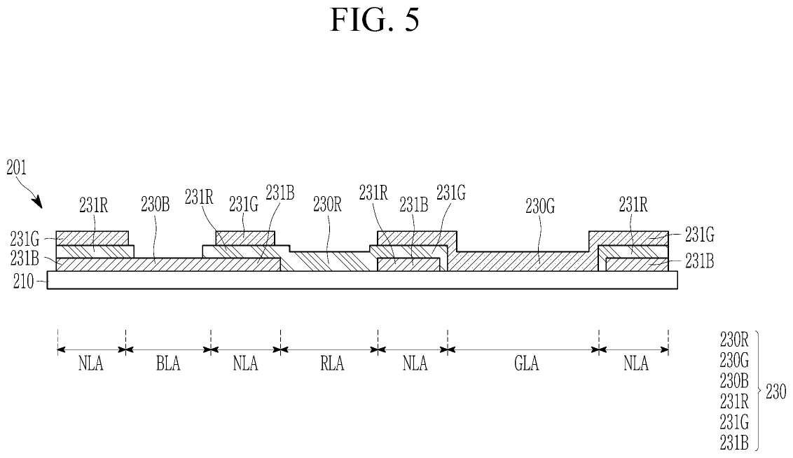

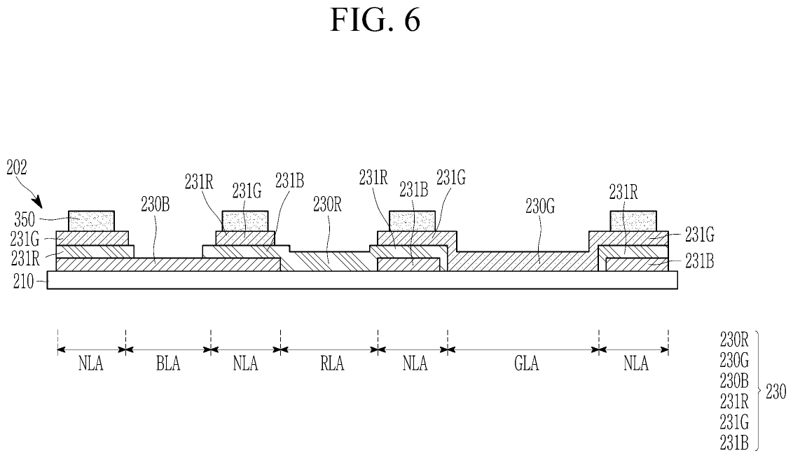

A color filter 230 including a blue color filter (or a first color filter) 230B, a red color filter (or a second color filter) 230R, and a green color filter (or a third color filter) 230G may be disposed on (or under) a second substrate 210. The color filter 230 may include multiple dummy color filters 231B, 231R, and 231G disposed in the non-emission area NLA. A specific stacked structure disposed on the second substrate 210 of the color filter panel 200 will be described below with reference to FIG. 5 and FIG. 6.

In an embodiment, the spacer 350 may be disposed on the first substrate 110 (and under the second substate 210). In another embodiment, the spacer 350 may be disposed on the second substrate 210 (and under the first substate 110). For example, the spacer 350 may overlap the bank 320 of the first substrate 110 in a plan view, and may overlap an area where the dummy color filters 231B, 231R, and 231G are disposed on the second substrate 210 in a plan view.

FIG. 3 and FIG. 4 are schematic cross-sectional views of a stacked structure on a first substrate of a display device (e.g., a display panel) according to an embodiment. The embodiment of FIG. 4 may be different from the embodiment of FIG. 3 in that the spacer 350 is further included.

Referring to FIG. 3, according to an embodiment, the display panel 101 may include a first substrate 110, multiple transistors TFT disposed on the first substrate 110, and an insulating layer 180 disposed on the first substate 110 and the transistors TFT. A first electrode 190 and a pixel defining layer 360 may be disposed on the insulating layer 180, and the first electrode 190 may be disposed inside an opening OP of the defining layer 360 and may be electrically connected to the transistor TFT.

Although not specifically illustrated, the transistor TFT may include a semiconductor layer, source and drain electrodes connected to the semiconductor layer, and a gate electrode insulated from the semiconductor layer. A second electrode 270 may be disposed on the pixel defining layer 360, and an emission layer EML may be disposed between the first electrode 190 and the second electrode 270. The emission layer EML may overlap the first electrode 190 and the second electrode 270 in a plan view. The first electrode 190, the second electrode 270, and the emission layer EML may constitute a light emitting device.

Multiple light emitting devices may emit light of different colors, or may emit light of same color. For example, the light emitting device may emit blue light. The light emitting devices may have structures in which light emitting devices emitting different colors are stacked each other. For example, in the light emitting devices, a light emitting layer emitting blue light and a light emitting layer emitting green light may be stacked each other. The pixel defining layer 360 may include a black material to prevent color mixing between adjacent light emitting devices.

An encapsulation layer 410 may be disposed on the light emitting device. In an embodiment, the encapsulation layer 410 may include an organic encapsulation layer 420 (e.g., a patterned organic encapsulation layer 420) and an inorganic encapsulation layer 430 disposed on the organic encapsulation layer 420. In another embodiment, an inorganic encapsulation layer (not illustrated) may be further included between the light emitting device and the organic encapsulation layer 420.

The organic encapsulation layer 420 may include an organic material such as an acryl- based resin, a methacrylic resin, polyisoprene, a vinyl-based resin, an epoxy-based resin, a urethane-based resin, a cellulose-based resin, a perylene-based resin, the like, and a combination thereof. The inorganic encapsulation layer 430 may include an inorganic material such as a silicon nitride (SiNₓ), a silicon oxide (SiOₓ), a silicon oxynitride (SiOₓNₓ), the like, and a combination thereof.

The organic encapsulation layer 420 may be formed by a solution process such as a spin coating, a slit coating, an inkjet process, or the like. The organic encapsulation layer 420 may be patterned and include a first opening OP1 in a portion overlapping (e.g., partially overlapping) the pixel defining layer 360 in a plan view. For example, the first opening OP1 may be formed by patterning the organic encapsulation layer 420 by a photolithography process.

The inorganic encapsulation layer 430 may be disposed on the organic encapsulation layer 420. The inorganic encapsulation layer 430 may be formed by a deposition process. For example, the inorganic encapsulation layer 430 may be disposed (e.g., be entirely disposed) on the first substrate 110 by a chemical vapor deposition (CVD) process. The inorganic encapsulation layer 430 may be formed in a curved shape corresponding to a pattern of the patterned organic encapsulation layer 420. The inorganic encapsulation layer 430 may include a concave portion corresponding to the first opening OP1 of the organic encapsulation layer 420. The encapsulation layer 410 may include the first opening OP1 patterned and overlapping (e.g., partially overlapping) the pixel defining layer 360 in a plan view.

A bank 320 may be disposed on the encapsulation layer 410. The bank 320 may overlap the pixel defining layer 360 in a plan view (or in a direction perpendicular to a surface of the first substrate 110, or in a thickness direction of the first substrate 110). The bank 320 may overlap the first opening OP1 of the patterned encapsulation layer 410 in a plan view. A portion of the bank 320 may be disposed (e.g., be partially disposed) inside first opening OP1.

The bank 320 may have a variety of colors including black, white, red, purple, blue, the like, and a combination thereof. The bank 320 may include a colored pigment, a colored dye, the like, or a combination thereof. The bank 320 may include a light blocking material, and the light blocking material may include an opaque inorganic insulating material including a metal oxide such as a titanium oxide (TiO₂), a chromium oxide (Cr₂O₃), a molybdenum oxide (MoO₃), the like, or a combination thereof, a black coloring agent, or the like. The black coloring agent may include a black dye, a black pigment, the like, or a combination thereof.

The bank 320 may include second openings OP2_W, OP2_R, and OP2_G corresponding to light emitting devices. The second openings OP2_W, OP2_R, and OP2_G may include a second-first opening OP2_W, a second-second opening OP2_R, and a second-third opening OP2_G. The bank 320 may fill the first opening OP1 of the encapsulation layer 410, and may partition the color conversion layer 330R and 330G and the transmission layer 330W. The color conversion layer may include a first color conversion layer 330R and a second color conversion layer 330G. The color conversion layers 330R and 330G and the transmission layer 330W may be disposed inside the second openings OP2_W, OP2_R, and OP2_G of the bank 320.

In an embodiment, since a portion of the bank 320 is also disposed inside the first opening OP1 of the patterned encapsulation layer 410, it is possible to effectively prevent color mixing between the light converted or transmitted between adjacent color conversion layers 330R and 330G and the transmission layer 330W. Referring to FIG. 3, lights L1 and L2 incident from the light emitting device may be absorbed by the bank 320 without transmitting to an adjacent emission area BLA, RLA, or GLA, thereby preventing color mixing between adjacent pixels.

The transmission layer 330W, the first color conversion layer 330R, and the second color conversion layer 330G may be disposed in the second-first opening OP2_W, the second- second opening OP2_R, and the second-third opening OP2_G, respectively. The transmission layer 330W, the first color conversion layer 330R, and the second color conversion layer 330G may be spaced apart from each other by the bank 320 disposed between the transmission layer 330W, the first color conversion layer 330R, and the second color conversion layer 330G.

The first color conversion layer 330R may be disposed in the red emission area RLA. The first color conversion layer 330R may convert light incident from the light emitting device to light of a first wavelength. The light of the first wavelength may be red light having a maximum emission peak wavelength in a range of about 600 nm to about 650 nm. For example, the light of the first wavelength may have a maximum emission peak wavelength in a range of about 620 nm to about 650 nm. The first color conversion layer 330R may be a red color conversion layer that converts incident light to red light.

The second color conversion layer 330G may be disposed in the green emission area GLA. The second color conversion layer 330G may convert light incident from the light emitting device to light of a second wavelength. The light of the second wavelength may be green light having a maximum emission peak wavelength in a range of about 500 nm to about 550 nm. For example, the light of the second wavelength may have a maximum emission peak wavelength in a range of about 510 nm to about 550 nm. The second color conversion layer 330G may be a green color conversion layer that converts incident light to green light.

The transmission layer 330W may be disposed in the blue emission area BLA. The transmission layer 330W may include a polymer resin and a scatterer included in the polymer resin. The transmission layer 330W may transmit light incident from the light emitting device. The light passing through the transmission layer 330W may be light of a third wavelength. The light of the third wavelength may be blue light having a maximum emission peak wavelength in a range of about 380 nm to about 480 nm. For example, the light of the third wavelength may have a maximum emission peak wavelength greater than or equal to about 420 nm. For example, the light of the third wavelength may have a maximum emission peak wavelength greater than or equal to about 430 nm. For example, the light of the third wavelength may have a maximum emission peak wavelength greater than or equal to about 440 nm. For example, the light of the third wavelength may have a maximum emission peak wavelength greater than or equal to about 445 nm. For example, the light of the third wavelength may have a maximum emission peak wavelength equal to or less than about 470 nm. For example, the light of the third wavelength may have a maximum emission peak wavelength equal to or less than about 460 nm. For example, the light of the third wavelength may have a maximum emission peak wavelength equal to or less than about 455 nm.

The first color conversion layer 330R and the second color conversion layer 330G may include first quantum dots and second quantum dots, respectively. For example, light incident to the first color conversion layer 330R may be converted to light of a first wavelength by the first quantum dots to be emitted, and light incident to the second color conversion layer 330G may be converted to light of a second wavelength by the second quantum dots to be emitted. The first color conversion layer 330R, the second color conversion layer 330G, and the transmission layer 330W may each include scatterers. The scatterers may scatter light incident to the first color conversion layer 330R, the second color conversion layer 330G, and the transmission layer 330W and improve light efficiency.

The quantum dots will be described in detail below.

Each of the first quantum dots and the second quantum dots (hereinafter, also referred to as semiconductor nanocrystals) may independently include a Group II-VI compound, a Group III-V compound, a Group IV-VI compound, a Group IV element or compound, a Group I-III-VI compound, a Group II-III-VI compound, a Group I-II-IV-VI compound, the like, or a combination thereof.

The Group II-VI compound may be selected from the group consisting of: a binary compound such as CdSe, CdTe, ZnS, ZnSe, ZnTe, ZnO, HgS, HgSe, HgTe, MgSe, MgS, and a mixture thereof; a ternary compound such as AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI compound may further include a Group III metal.

The Group III-V compound may be selected from the group consisting of: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a mixture thereof; and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The Group III-V compound may further include a Group II metal (e.g., InZnP).

The Group IV-VI compound may be selected from the group consisting of: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; and a quaternary compound such as SnPbSSe, SnPbSeTe, SnPbSTe, and a mixture thereof.

The Group IV element or compound may be selected from the group consisting of: a unary compound such as Si, Ge, and a combination thereof; and a binary compound such as SiC, SiGe, and a combination thereof, but the disclosure is not limited thereto.

For example, the Group I-III-VI compound may include CuInSe₂, CuInS₂, CuInGaSe, CuInGaS, and a combination thereof, but the disclosure is not limited thereto. For example, the Group I-II-IV-VI compound may include CuZnSnSe, CuZnSnS, and a combination thereof, but the disclosure is not limited thereto. The Group IV element or compound may be selected from the group consisting of: a unary compound such as Si, Ge, and a mixture thereof; and a binary compound such as SiC, SiGe, and a mixture thereof.

The Group II-III-VI compound may be selected from ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and a combination thereof, but the disclosure is not limited thereto.

The Group I-II-IV-VI compound may be selected from CuZnSnSe, CuZnSnS, and a combination thereof, but the disclosure is not limited thereto.

In an embodiment, the quantum dots may not include cadmium. The quantum dots may include semiconductor nanocrystals including a Group III-V compound including indium and phosphorus. The Group III-V compound may further include zinc. The quantum dots may include semiconductor nanocrystals including a Group II-VI compound including a chalcogen element (e.g., sulfur, selenium, tellurium, or a combination thereof) and zinc.

In the quantum dots, the binary compound, the ternary compound, and/or the quaternary compound may be each present in particles at uniform concentrations, or they may be each divided into states having partially different concentrations to be present in a same particle. A core-shell structure in which some quantum dots surround some other quantum dots may be possible. The shell may have a concentration gradient in which a concentration of elements of the shell decreases toward a center of the core.

In an embodiment, the quantum dot may have a core-shell structure that includes a core including the semiconductor nanocrystal and a shell surrounding the core. The shell of the quantum dot may serve as a passivation layer for maintaining a semiconductor characteristic and/or as a charging layer for applying an electrophoretic characteristic to the quantum dot by preventing chemical denaturation of the core. The shell may be a single layer or a multilayer. The shell may have a concentration gradient in which a concentration of elements of the shell decreases toward a center of the core. For example, the shell of the quantum dot may include a metal or a nonmetal oxide, a semiconductor compound, the like, or a combination thereof.

For example, the metal or the nonmetal oxide may be: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like; or a ternary compound such as MgAl₂O₄, CoFe₂O₄, NiFe₂O₄, CoMn₂O₄, and the like, but the disclosure is not limited thereto.

For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the disclosure is not limited thereto.

The shell may have a concentration gradient in which a concentration of elements of the shell decreases toward a center of the core. The semiconductor nanocrystal may have a structure including a semiconductor nanocrystal core and a multilayered shell surrounding the semiconductor nanocrystal core. In an embodiment, the multilayered shell may have two or more layers such as two, three, four, five, or more layers. The two adjacent layers of the shell may have a single composition or different compositions. Each layer in the multilayered shell may have a composition that varies depending on a distance from the center of the core.

The quantum dot may have a full width at half maximum (FWHM) of the light-emitting wavelength spectrum equal to or less than about 45 nm. For example, the quantum dot may have the FWHM of the light-emitting wavelength spectrum of equal to or less than about 40 nm. For example, the quantum dot may have the FWHM of the light-emitting wavelength spectrum of equal to or less than about 30 nm. In this range of the FWHM of the light-emitting wavelength spectrum, color purity or color reproducibility may be improved. Since light emitted through the quantum dot is emitted in all directions, a viewing angle of light may be improved.

In the quantum dot, a shell material and a core material may have different energy bandgaps. For example, an energy bandgap of the shell material may be greater than an energy bandgap of the core material. In another embodiment, the energy bandgap of the shell material may be less than the energy bandgap of the core material. The quantum dot may have a multilayered shell. In the multilayered shell, an energy bandgap of an outer layer may be greater than an energy bandgap of an inner layer (i.e., a layer closer to the core). In the multilayered shell, the energy bandgap of the outer layer may be less than the energy bandgap of the inner layer.

The quantum dot may control an absorption/emission wavelength by controlling a composition and size of the quantum dot. A maximum emission peak wavelength of the quantum dot may be in a wavelength range of ultraviolet rays to infrared rays or greater.

The quantum dots may have quantum efficiency of greater than or equal to about 10%. For example, the quantum dots may have quantum efficiency of greater than or equal to about 30%. For example, the quantum dots may have quantum efficiency of greater than or equal to about 50%. For example, the quantum dots may have quantum efficiency of greater than or equal to about 60%. For example, the quantum dots may have quantum efficiency of greater than or equal to about 70%. For example, the quantum dots may have quantum efficiency of greater than or equal to about 90%. For example, the quantum dots may have quantum efficiency of about 100%. The quantum dots may have a relatively narrow spectrum. For example, the quantum dots may have a half-width of an emission wavelength spectrum of equal to or less than about 50 nm. For example, the quantum dots may have a half-width of an emission wavelength spectrum of equal to or less than about 45 nm. For example, the quantum dots may have a half-width of an emission wavelength spectrum of equal to or less than about 40 nm. For example, the quantum dots may have a half-width of an emission wavelength spectrum of equal to or less than about 30 nm.

The quantum dots may have a particle size in a range of about 1 nm to about 100 nm. The particle size may be a particle diameter or a diameter converted by assuming a spherical shape from a two-dimensional image obtained by transmission electron microscope analysis. The quantum dots may have a size in a range of about 1 nm to about 20 nm. For example, the quantum dots may have a size greater than or equal to about 2 nm. For example, the quantum dots may have a size greater than or equal to about 3 nm. For example, the quantum dots may have a size in a range of about 4 nm to about 50 nm. For example, the quantum dots may have a size equal to or less than about 40 nm. For example, the quantum dots may have a size equal to or less than about 30 nm. For example, the quantum dots may have a size equal to or less than about 20 nm. For example, the quantum dots may have a size equal to or less than about 15 nm. For example, the quantum dots may have a size equal to or less than about 10 nm. A shape of the quantum dot is not particularly limited. For example, the shape of the quantum dot may include a sphere, a polyhedron, a pyramid, a multipod, a square, a cuboid, a nanotube, a nanorod, a nanowire, a nanosheet, the like, or a combination thereof, but the disclosure is not limited thereto.

The quantum dots may be commercially available or may be appropriately synthesized. For the quantum dots, the particle size may be controlled relatively freely during colloid synthesis, and the particle size may be uniformly controlled.

The quantum dot may include an organic ligand (e.g., having a hydrophobic moiety and/or a hydrophilic moiety). An organic ligand may be bonded to a surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, the like, or a combination thereof, each R may independently be a C3 to C40 (e.g., C5 or more and C24 or less) substituted or unsubstituted alkyl, a C3 to C40 substituted or unsubstituted aliphatic hydrocarbon group such as a substituted or unsubstituted alkenyl or the like, a C6 to C40 (e.g., C6 or more and C20 or less) substituted or unsubstituted aromatic hydrocarbon group such as a substituted or unsubstituted C6 to C40 aryl group or the like, or a combination thereof.

For example, the organic ligand may include: a thiol compound such as methane thiol, ethane thiol, propane thiol, butane thiol, pentane thiol, hexane thiol, octane thiol, dodecane thiol, hexadecane thiol, octadecane thiol, benzyl thiol, or the like; an amine such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributylamine, trioctylamine or the like; a carboxylic acid compound such as methanic acid, ethanic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, or the like; a phosphine compound such as methyl phosphine, ethyl phosphine, propyl phosphine, butyl phosphine, pentyl phosphine, octyl phosphine, dioctyl phosphine, tributylphosphine, trioctylphosphine, or the like; a phosphine compound or an oxide compound of the phosphine compound such as methyl phosphine oxide, ethyl phosphine oxide, propyl phosphine oxide, butyl phosphine oxide, pentyl phosphine oxide, tributylphosphine oxide, octyl phosphine oxide, dioctyl phosphine oxide, trioctylphosphine oxide, or the like; diphenyl phosphine, a triphenyl phosphine compound or an oxide compound thereof; or a C5 to C20 alkyl phosphinic acid such as hexylphosphinic acid, octylphosphinic acid, dodecanephosphinic acid, tetradecanephosphinic acid, hexadecanephosphinic acid, octadecanephosphinic acid, or the like, the like, or a combination thereof, but the disclosure is not limited thereto. The quantum dot may include a hydrophobic organic ligand alone or a mixture of one or more. The hydrophobic organic ligand (e.g., an acrylate group, a methacrylate group, or the like) may not include a photopolymerizable moiety.

As described above, in the display device according to an embodiment, the red light emitting area RLA may convert incident light to red light and emit the red light, and the green light emitting area GLA may convert incident light to green light and emit the green light. The blue emission area BLA may transmit incident light without color conversion. For example, the incident light may be blue light. Accordingly, as the incident light emitted from the light emitting device is converted or transmitted to red light, green light, and blue light while passing through the first color conversion layer 330R, the second color conversion layer 330G, and the transmission layer 330W, a color image may be displayed.

Referring to FIG. 4, a display panel 102 according to an embodiment may further include a spacer 350.

The spacer 350 may overlap the pixel definition layer 360 and the bank 320 in a plan view. The spacer 350 may surround at least a portion of the emission areas BLA, RLA, and GLA in a plan view.

The spacer 350 may have a variety of colors including black, white, red, purple, blue, the like, and a combination thereof. The spacer 350 may include a colored pigment, a colored dye, the like, or a combination thereof. The spacer 350 may include a light blocking material, and the light blocking material may include an opaque inorganic insulating material including a metal oxide such as a titanium oxide (TiO₂), a chromium oxide (Cr₂O₃), a molybdenum oxide (MoO₃), the like, or a combination thereof, a black coloring agent, or the like. The black coloring agent may include a black dye, a black pigment, the like, or a combination thereof. The spacer 350 may include a colored material and block light, and may prevent color mixing between adjacent ones (or neighboring ones) of the emission areas BLA, RLA, and GLA.

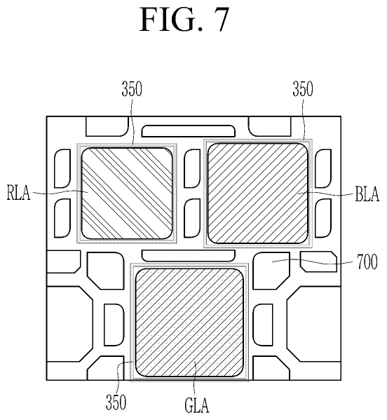

The spacer 350 may be disposed adjacent to the emission area BLA, RLA, or GLA. The spacer 350 may surround at least a portion of the emission areas BLA, RLA, and GLA in a plan view and block color mixing of light not excited by the color conversion layer. For example, the light L3 (see FIG. 2) not excited by the color conversion layer 330R or 330GG may be absorbed by the spacer 350 and not propagate to an adjacent emission area BLA, RLA, or GLA, thereby blocking color mixing. Disposition of the spacer 350 in a plan view will be described in detail with reference to FIG. 7 to FIG. 11 below.

FIG. 5 and FIG. 6 are schematic cross-sectional views of a stacked structure on a second substrate of a display device (e.g., a color filter panel) according to an embodiment. The embodiment of FIG. 6 may be different from the embodiment of FIG. 5 in that the spacer 350 is further included.

Referring to FIG. 5, a color filter panel 201 according to an embodiment may include a second substrate 210 and a color filter 230 on the second substrate 210.

Referring to FIG. 5, the color filter 230 including a blue color filter 230B, a red color filter 230R, and a green color filter 230G may be disposed on the second substrate 210.

The blue color filter 230B and a blue dummy color filter (or a third dummy color filter) 231B may be disposed on a same layer. The blue color filter 230B may be disposed in a blue emission area BLA, and the blue dummy color filter 231B may be disposed in a non-emission area NLA overlapping a bank (see, e.g., 320 of FIG.2) in a plan view. Although the blue color filter 230B and the blue dummy color filter 231B are illustrated as separate components in FIG. 5, the blue color filter 230B and the blue dummy color filter 231B may be connected in a plan view or integral with each other.

For example, the blue color filter may be disposed in an area (e.g., an entire area) except for a green emission area GLA and a red emission area RLA. Among the blue color filters, a blue color filter disposed in the blue emission area BLA may be the blue color filter 230B, and a blue color filter disposed in the non-emission area NLA may be the blue dummy color filter 231B. Opposite edges of the blue color filter 230B may be disposed in a non-emission area NLA overlapping the bank in a plan view, and be the blue dummy color filter 231B.

The red color filter 230R and a red dummy color filter (or a second dummy color filter) 231R may be disposed on the blue color filter 230B and the blue dummy color filter 231B.

The red color filter 230R may be disposed in a red emission area RLA, and the red dummy color filter 231R may be disposed in a non-emission area NLA overlapping a bank (see, e.g., 320 of FIG. 2) in a plan view. Although the red color filter 230R and the red dummy color filter 231R are illustrated as separate components in FIG. 5, the red color filter 230R and the red dummy color filter 231R may be connected in a plan view or integral with each other.

For example, the red color filter may be disposed in an area (e.g., an entire area) except for a green emission area GLA and a blue emission area BLA. Among the red color filters, a red color filter disposed in the red emission area RLA may be the red color filter 230R, and a red color filter disposed in the non-emission area NLA may be the red dummy color filter 231R. In FIG. 5, opposite edges of the red color filter 230R may be disposed in the non-emission area NLA overlapping the bank in a plan view, and be a red dummy color filter 231R.

The green color filter 230G and a green dummy color filter (or a first dummy color filter) 231G may be disposed on the red color filter 230R and the red dummy color filter 231R. The green color filter 230G may be disposed in a green emission area GLA, and the green dummy color filter 231G may be disposed in a non-emission area NLA overlapping a bank (see, e.g., 320 of FIG. 2) in a plan view. Although the green color filter 230G and the green dummy color filter 231G are illustrated as separate components in FIG. 5, the green color filter 230G and the green dummy color filter 231G may be connected in a plan view or integral with each other.

For example, the green color filter may be disposed in an area (e.g., an entire area) except for a blue emission area BLA and a red emission area RLA. Among the green color filters, a green color filter disposed in the green emission area GLA may be the green color filter 230G, and a green color filter disposed in the non-emission area NLA may be the green dummy color filter 231G. In FIG. 5, opposite edges of the green color filter 230G may be disposed in the non-emission area NLA overlapping the bank in a plan view, and be a green dummy color filter 231G.

Referring to FIG. 5, the blue dummy color filter 231B, the red dummy color filter 231R, and the green dummy color filter 231G may overlap each other in the non-emission area NLA in a plan view. The blue dummy color filter 231B, the red dummy color filter 231R, and the green dummy color filter 231G may form a color filter overlapping body 231B, 231R, and 231G. The color filter overlapping body 231B, 231R, and 231G may block light in the non-emission area NLA, similarly to a light blocking member.

Referring to FIG. 6, a color filter panel 202 according to an embodiment may further include a spacer 350.

The spacer 350 may overlap the color filter overlapping body 231B, 231R, and 231G in a plan view (or in a direction perpendicular to a surface of the second substrate 210, or in a thickness direction of the second substrate 210). The spacer 350 may surround at least a portion of the emission areas BLA, RLA, and GLA in a plan view.

The spacer 350 may include a light blocking material, and the light blocking material may include an opaque inorganic insulating material including a metal oxide such as a titanium oxide (TiO₂), a chromium oxide (Cr₂O₃), a molybdenum oxide (MoO₃), the like, or a combination thereof, a black coloring agent, or the like. The black coloring agent may include a black dye, a black pigment, the like, or a combination thereof. The spacer 350 may include a colored material and block light, and may prevent color mixing between neighboring emission areas. The spacer 350 may surround at least a portion of the emission areas BLA, RLA, and GLA in a plan view and block color mixing of light that are is excited by a color conversion layer (see, e.g., 330R or 330G of FIG. 2).

FIG. 7 to FIG. 11 are schematic plan views of emission areas of a display device according to an embodiment. In the display device according to an embodiment, a color conversion layer (see, e.g., 330R or 330G of FIG. 2) may be disposed in a red emission area RLA and the green emission area GLA, and a transmission layer (see, e.g., 330W of FIG. 2) may be disposed in the blue emission area BLA. In FIG. 7 to FIG. 11, a spacer 350 and a well 700 are illustrated.

As described above, the spacer 350 may include a colored material and may block light traveling to an adjacent emission area BLA, RLA, or GLA. Accordingly, color mixing between the emission areas BLA, RLA, and GLA may be prevented. The spacer 350 may surround at least a portion of each of the emission areas BLA, RLA, and GLA in a plan view.

The well 700, which is a recessed portion, may be an area where a residual material from an inkjet process collects. For example, in case that the color conversion layer is formed by an inkjet process, a residual inkjet material may pool in the well 700 and may not invade other emission areas BLA, RLA, or GLA.

Referring to FIG. 7, the spacer 350 may surround all four surfaces of each of the emission areas BLA, RLA, and GLA in a plan view. The spacer 350 may include a light-blocking material to prevent color mixing between adjacent emission areas BLA, RLA, and GLA.

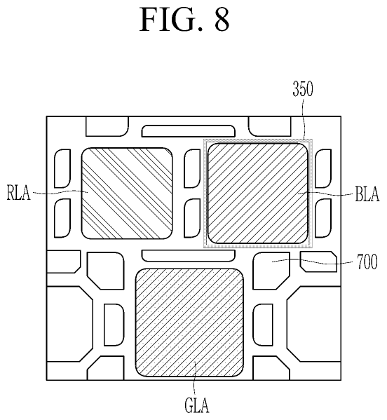

Referring to FIG. 8, the spacer 350 may surround the blue emission area BLA in a plan view. The spacer 350 may be disposed around the blue emission area BLA and block blue light transmitted from the blue emission area BLA from traveling to the emission areas RLA and GLA adjacent to the blue emission area BLA.

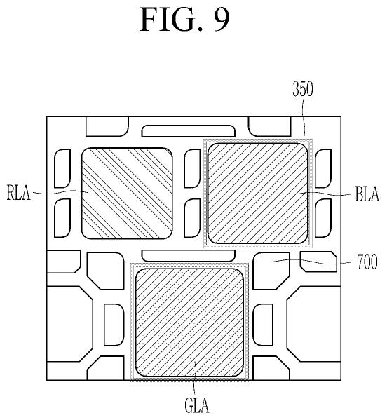

Referring to FIG. 9, the spacers 350 may surround the blue emission area BLA and the green emission area GLA in a plan view. The spacer 350 disposed around the blue emission area BLA may block blue light transmitted from the blue emission area BLA from traveling to the emission areas RLA and GLA adjacent to the blue emission area BLA. The spacer 350 disposed around the green light emitting area GLA may block the blue light that is not excited by a color conversion layer (see, e.g., 330G of FIG. 2) from traveling to the light emitting regions BLA and RLA adjacent to the blue emission area BLA.

In another embodiment, a position and a disposition relationship of the spacer 350 may be variously changed.

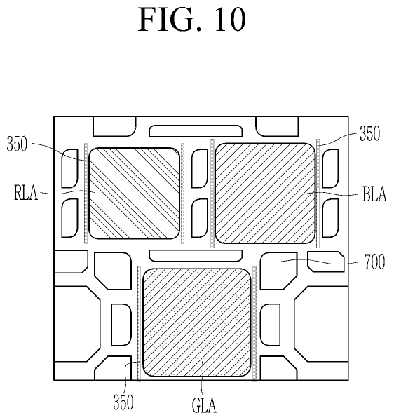

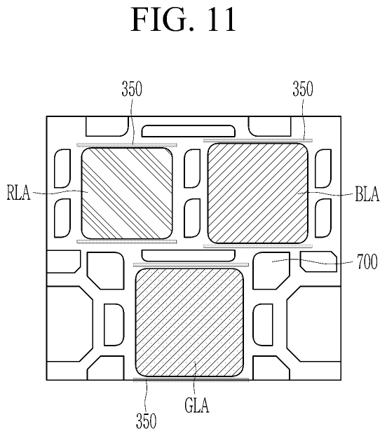

FIG. 7 to FIG. 9 illustrate the spacer 350 surrounding a boundary of the emission area BLA, RLA, or GLA, but the spacer 350 may be selectively disposed on a portion of the emission area BLA, RLA, or GLA as illustrated in FIG. 10 and FIG. 11. The spacer 350 may block blue light transmitted from the blue emission area BLA or blue light not excited by the color conversion layer (see, e.g., 330R or 330G of FIG. 2) from traveling to the emission areas RLA and GLA adjacent to the blue emission area BLA.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a plurality of light emitting devices disposed on a substrate, each including a first electrode, an emission layer, and a second electrode;
a pixel defining layer including a plurality of openings overlapping the first electrode in a plan view;
an encapsulation layer covering the plurality of light emitting devices and including a plurality of first openings overlapping the pixel defining layer in a plan view;
a bank disposed on the encapsulation layer, overlapping the plurality of first openings in a plan view, and including a plurality of second openings overlapping the plurality of light emitting devices in a plan view;
a first color conversion layer, a second color conversion layer, and a transmission layer, each disposed inside the plurality of second openings; and
a spacer disposed on the bank and including a colored material.

2. The display device of claim 1, wherein the plurality of second openings each includes:
a first emission area overlapping the transmission layer in a plan view;
a second emission area overlapping the first color conversion layer in a plan view; and
a third emission area overlapping the second color conversion layer in a plan view.

3. The display device of claim 2, further comprising:
a first color filter overlapping the transmission layer in a plan view;
a second color filter overlapping the first color conversion layer in a plan view; and
a third color filter overlapping the second color conversion layer in a plan view.

4. The display device of claim 3, further comprising:
a first dummy color filter disposed on the spacer;
a second dummy color filter disposed on the first dummy color filter; and
a third dummy color filter disposed on the second dummy color filter.

5. The display device of claim 2, wherein the spacer surrounds a portion of at least one of the first emission area, the second emission area, and the third emission area in a plan view.

6. The display device of claim 2, wherein the spacer completely surrounds at least one of the first emission area, the second emission area, and the third emission area in a plan view.

7. The display device of claim 1, wherein the encapsulation layer includes:
an organic encapsulation layer including the plurality of first openings overlapping the pixel defining layer in a plan view; and
an inorganic encapsulation layer disposed on the organic encapsulation layer.

8. The display device of claim 7, wherein the bank contacts the inorganic encapsulation layer.

9. The display device of claim 1, wherein at least a portion of the bank is disposed inside the plurality of first openings.

10. The display device of claim 4, wherein the pixel defining layer, the bank, the spacer, the first dummy color filter, the second dummy color filter, and the third dummy color filter overlap each other in a plan view.

11. A display device comprising:
a display panel; and
a color filter panel overlapping the display panel in a plan view, wherein
the display panel includes:
a first substrate;
a plurality of light emitting devices disposed on the first substrate, each including a first electrode, an emission layer, and a second electrode;
a pixel defining layer including a plurality of openings overlapping the first electrode in a plan view;
an encapsulation layer covering the plurality of light emitting devices and including a plurality of first openings overlapping the pixel defining layer in a plan view;
a bank disposed on the encapsulation layer, overlapping the plurality of first openings in a plan view, and including a plurality of second openings overlapping the plurality of light emitting devices in a plan view; and
a first color conversion layer, a second color conversion layer, and a transmission layer, each disposed inside the plurality of second openings, and the color filter panel includes:
a second substrate;
a color filter disposed on the second substrate; and
a spacer disposed on the color filter and including a colored material.

12. The display device of claim 11, wherein the plurality of second openings each includes:
a first emission area overlapping the transmission layer in a plan view;
a second emission area overlapping the first color conversion layer in a plan view; and
a third emission area overlapping the second color conversion layer in a plan view.

13. The display device of claim 12, wherein the color filter includes:
a first color filter overlapping the transmission layer in a plan view;
a second color filter overlapping the first color conversion layer in a plan view; and
a third color filter overlapping the second color conversion layer in a plan view.

14. The display device of claim 13, wherein the color filter further includes:
a first dummy color filter overlapping the spacer in a plan view;
a second dummy color filter overlapping the first dummy color filter in a plan view; and
a third dummy color filter overlapping the second dummy color filter in a plan view.

15. The display device of claim 12, wherein the spacer surrounds a portion of at least one of the first emission area, the second emission area, and the third emission area in a plan view.

16. The display device of claim 12, wherein the spacer completely surrounds at least one of the first emission area, the second emission area, and the third emission area in a plan view.

17. The display device of claim 11, wherein the encapsulation layer includes:
an organic encapsulation layer including the plurality of first openings overlapping the pixel defining layer in a plan view; and
an inorganic encapsulation layer disposed on the organic encapsulation layer.

18. The display device of claim 17, wherein the bank contacts the inorganic encapsulation layer.

19. The display device of claim 11, wherein at least a portion of the bank is disposed inside the plurality of first openings.

20. The display device of claim 14, wherein the pixel defining layer, the bank, the spacer, the first dummy color filter, the second dummy color filter, and the third dummy color filter overlap each other in a plan view.
